(19) United States
(12) Patent Application Publication
(10) Pub. No.: US 2026/0293179 A1
(43) Pub. Date: Sep. 24, 2026

(54) TRANSISTOR DEVICE, SEMICONDUCTOR EPITAXIAL STRUCTURE, AND PREPARATION METHOD THEREOF

(71) Applicant: HUNAN SAN'AN SEMICONDUCTOR CO., LTD., Changsha (CN)

(72) Inventors: Hui ZHANG, Changsha (CN); Cheng Liu, Changsha (CN); Nientze YEH, Changsha (CN); Han Xu, Changsha (CN); Zongrui Cai, Changsha (CN); Yuanming Li, Changsha (CN)

(21) Appl. No.: 19/678,453

(22) Filed: May 15, 2026

Related U.S. Application Data
(63) Continuation of application No. PCT/CN2023/134045, filed on Nov. 24, 2023.

(51) Int. Cl. H10D 30/47; H10D 62/824

(52) U.S. Cl. CPC H10D 30/471; H10D 62/824

(57) ABSTRACT

A transistor device, a semiconductor epitaxial structure, and a preparation method thereof are provided. The transistor device includes: a substrate; a compound semiconductor composite structure having a two-dimensional electron gas and disposed on the substrate; a first cap layer disposed on the compound semiconductor composite structure; an insertion layer disposed on the first cap layer; a second cap layer disposed on the insertion layer; and a gate metal disposed on the second cap layer. A bandgap of a material of the insertion layer is greater than bandgaps of materials of the first cap layer and the second cap layer. Along a direction from the first cap layer to the second cap layer, the bandgap of the material of the insertion layer first increases and then decreases. Thus, on-state gate leakage is reduced, and the gate voltage withstand capability and voltage withstand swing of the device are increased.

### TECHNICAL FIELD

The disclosure relates to the technical field of semiconductors, and more particularly to a transistor device, a semiconductor epitaxial structure, and a preparation method thereof.

### BACKGROUND

Transistor devices form ohmic or Schottky contacts between a gate metal and a surface of an epitaxial layer by including the epitaxial layer and the gate metal placed on the surface of the epitaxial layer. When the device is turned on, a relatively large gate leakage current occurs.

### SUMMARY

A transistor device, a semiconductor epitaxial structure, and a preparation method thereof provided in the disclosure are intended to reduce on-state gate leakage.

To solve the above technical problem, a first technical solution provided by the disclosure is a transistor device, including: a substrate; a compound semiconductor composite structure, a first cap layer, an insertion layer, a second cap layer, and a gate metal. The compound semiconductor composite structure has a two-dimensional electron gas and is disposed on the substrate. The first cap layer is disposed on the compound semiconductor composite structure. The insertion layer is disposed on the first cap layer. The second cap layer is disposed on the insertion layer. A bandgap of a material of the insertion layer is greater than bandgaps of materials of the first cap layer and the second cap layer, respectively. Along a direction from the first cap layer to the second cap layer, the bandgap of the material of the insertion layer first increases and then decreases. The gate metal is disposed on the second cap layer.

To solve the above technical problem, a second technical solution provided by the disclosure is a semiconductor epitaxial structure, including: a substrate; a compound semiconductor composite structure, and a cap layer. The compound semiconductor composite structure has a two-dimensional electron gas and is disposed on the substrate. The cap layer is disposed on the compound semiconductor composite structure. The cap layer includes a first cap layer disposed on the compound semiconductor composite structure, an insertion layer disposed on the first cap layer, and a second cap layer disposed on the insertion layer. A bandgap of a material of the insertion layer is greater than bandgaps of materials of the first cap layer and the second cap layer, respectively. Along a direction from the first cap layer to the second cap layer, the bandgap of the material of the insertion layer first increases and then decreases.

To solve the above technical problem, a third technical solution provided by the disclosure is a preparation method of a semiconductor epitaxial structure, the method including: providing a substrate; forming a compound semiconductor composite structure having a two-dimensional electron gas on the substrate; and forming a cap layer on the compound semiconductor composite structure. The cap layer includes a first cap layer disposed on the compound semiconductor composite structure, an insertion layer disposed on the first cap layer, and a second cap layer disposed on the insertion layer. A bandgap of a material of the insertion layer is greater than bandgaps of materials of the first cap layer and the second cap layer, respectively. Along a direction from the first cap layer to the second cap layer, the bandgap of the material of the insertion layer first increases and then decreases.

Beneficial effects of the disclosure are as follows. Different from the related art, the disclosure discloses the transistor device, the semiconductor epitaxial structure, and the preparation method thereof. The transistor device includes: the substrate; the compound semiconductor composite structure, the first cap layer, the insertion layer, the second cap layer, and a gate metal. The compound semiconductor composite structure has a two-dimensional electron gas and is disposed on the substrate. The first cap layer is disposed on the compound semiconductor composite structure. The insertion layer is disposed on the first cap layer. The second cap layer is disposed on the insertion layer. The bandgap of a material of the insertion layer is greater than bandgaps of materials of the first cap layer and the second cap layer, respectively. Along the direction from the first cap layer to the second cap layer, the bandgap of the material of the insertion layer first increases and then decreases. The gate metal is disposed on the second cap layer. By providing the insertion layer between the first cap layer and the second cap layer, and by making the bandgap of the material of the insertion layer greater than the bandgap of the second cap layer, a spike is generated in the energy band of the cap layer, thereby reducing on-state gate leakage, increasing the gate voltage withstand capability and voltage withstand swing of the device, and improving the gate reliability of the device. By configuring the bandgap of the material of the insertion layer to first increase and then decrease, polarization occurs between the insertion layer and the first and second cap layers, making the spike generated in the energy band of the cap layer more pronounced, which further helps to reduce on-state gate leakage.

### BRIEF DESCRIPTION OF DRAWINGS

To more clearly illustrate technical solutions in embodiments of the disclosure, the following briefly introduces the accompanying drawings required for the description of the embodiments. Apparently, the accompanying drawings in the following description are only some embodiments of the disclosure, and for those skilled in the art, other drawings can be obtained from these drawings without creative effort.

FIG. 1 is a schematic structural diagram of a transistor device according to an embodiment of the disclosure.

FIG. 2 is a schematic structural diagram of a cap layer of the transistor device shown in FIG. 1.

FIG. 3 is a schematic diagram showing a variation manner of a bandgap of a material in the cap layer shown in FIG. 2.

FIG. 4 is an energy band diagram of the structure shown in FIG. 3.

FIG. 5 is a schematic structural diagram of another cap layer of the transistor device shown in FIG. 1.

FIG. 6 is a schematic diagram showing a variation manner of a bandgap of a material in the cap layer shown in FIG. 5.

FIG. 7 is a schematic diagram showing another variation manner of a bandgap of a material in the cap layer shown in FIG. 5.

FIG. 8 is a diagram showing a relationship between bandgap and composition of AlₓIn_{y}Ga_{1-x-y}N.

FIG. 9 is a schematic diagram comparing energy bands for different doping conditions of an insertion layer of the transistor device according to the embodiment of the disclosure.

FIG. 10 is a schematic diagram comparing gate leakage currents for different doping conditions of the insertion layer of the transistor device according to the embodiment of the disclosure.

FIG. 11 is an experimental comparison diagram of I_{D}-V_{G} between the transistor device according to the embodiment of the disclosure and an existing transistor device.

FIG. 12 is an experimental comparison diagram of I_{G}-V_{G} between the transistor device according to the embodiment of the disclosure and the existing transistor device.

FIG. 13 is a schematic structural diagram of a semiconductor epitaxial structure according to an embodiment of the disclosure.

### DETAILED DESCRIPTION OF EMBODIMENTS

Technical solutions in embodiments of the disclosure will be clearly and completely described below in conjunction with the accompanying drawings of the embodiments of the disclosure. Apparently, the described embodiments are only some of the embodiments of the disclosure, not all of them. Based on the embodiments in the disclosure, all other embodiments obtained by those skilled in the art without making creative efforts shall fall within the scope of protection of the disclosure.

In the following description, specific details such as particular system structures, interfaces, and technologies are set forth for purposes of illustration rather than limitation to provide a thorough understanding of the disclosure.

The terms “first”, “second”, and “third” in the disclosure are used for descriptive purposes only and are not to be construed as indicating or implying relative importance or implicitly indicating the number of technical features indicated. Thus, a feature defined as “first”, “second”, or “third” may explicitly or implicitly include at least one of said features. In the description of the disclosure, “a plurality of” means at least two, for example two, three, etc., unless otherwise expressly and specifically defined. All directional indications (such as up, down, left, right, front, back, etc.) in the embodiments of the disclosure are only used to explain the relative positional relationship and movement conditions among components in a specific posture (as shown in the accompanying drawings). If the specific posture changes, the directional indication will also change accordingly. The terms “including” and “having” and any variations thereof in the embodiments of the disclosure are intended to cover non-exclusive inclusion. For example, a process, a method, a system, a product, or a device that includes a series of steps or units is not limited to the listed steps or units, but optionally also includes steps or units not listed, or optionally also includes other steps or components inherent to such process, method, product, or device.

Reference to “an embodiment” herein means that a particular feature, structure, or characteristic described in connection with the embodiment may be included in at least one embodiment of the disclosure. The appearances of the phrase in various places in the specification are not necessarily all referring to the same embodiment, nor are they separate or alternative embodiments mutually exclusive with other embodiments. It is explicitly and implicitly understood by those skilled in the art that the embodiments described herein may be combined with other embodiments.

The disclosure will be described in detail below with reference to the accompanying drawings and embodiments.

Due to the spontaneous polarization and piezoelectric polarization effects of wide-bandgap semiconductor gallium nitride-based materials (GaN, AlGaN, InGaN, etc.), a high-density and high-mobility two-dimensional electron gas (2-DEG) is generated in the AlGaN/GaN heterojunction channel, making GaN-based high electron mobility transistor (HEMT) devices a solution for high-efficiency, high-power-density power devices, providing larger breakdown voltage and power density. Under zero gate bias, the 2-DEG present in the channel makes the device conductive, and the device threshold voltage is negative (depletion-mode device). For safety and to simplify the gate drive circuit in GaN power devices, it is necessary to have the channel off under zero bias and the threshold voltage positive (enhancement-mode device). Currently, P type GaN (PGaN) gate structures are commonly used to achieve enhancement-mode in GaN HEMT devices. The gate metal of a PGaN gate HEMT device typically forms an ohmic or Schottky contact with the underlying PGaN, resulting in a relatively large gate leakage current when the device is turned on, which leads to weak gate voltage withstand capability, small gate voltage swing, and poor gate reliability.

In view of this, an embodiment of the disclosure provides a transistor device.

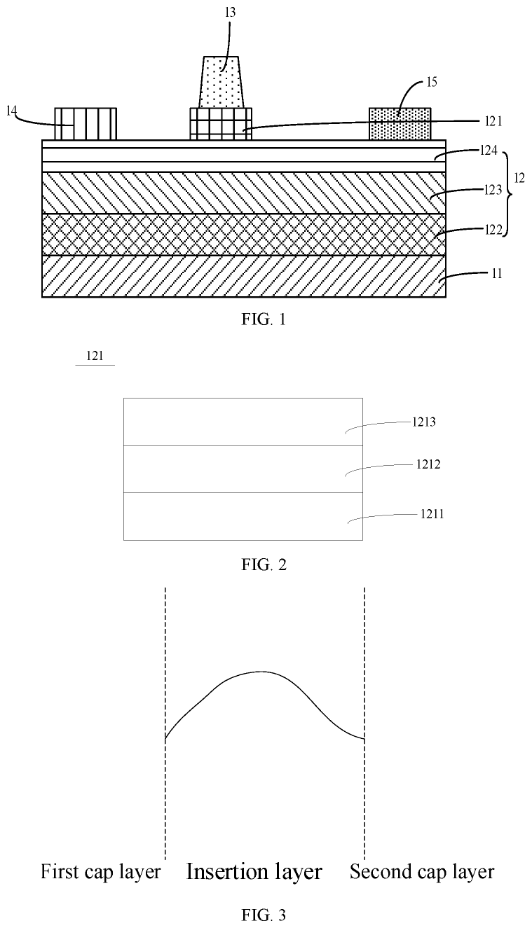

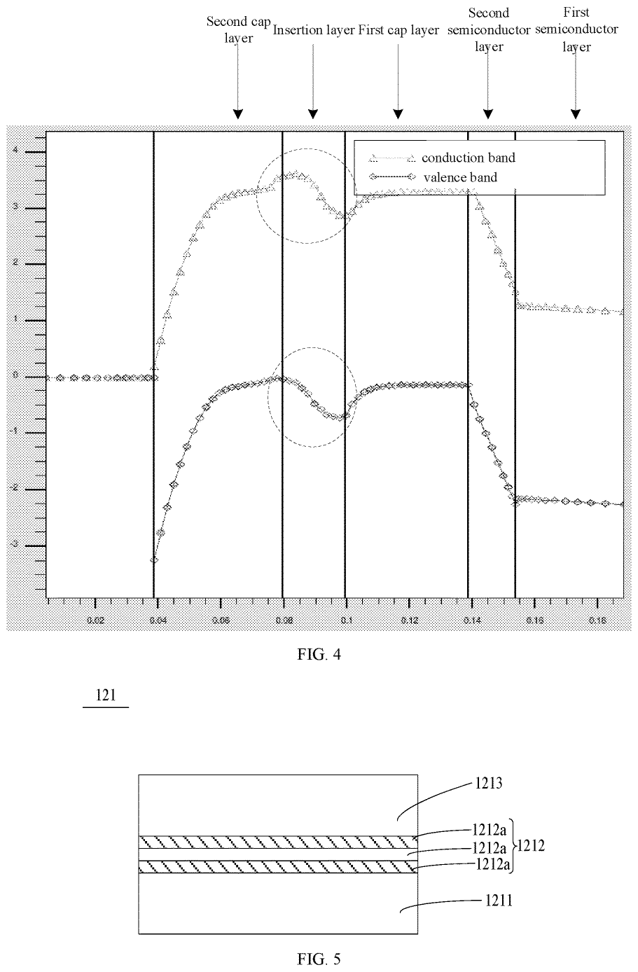

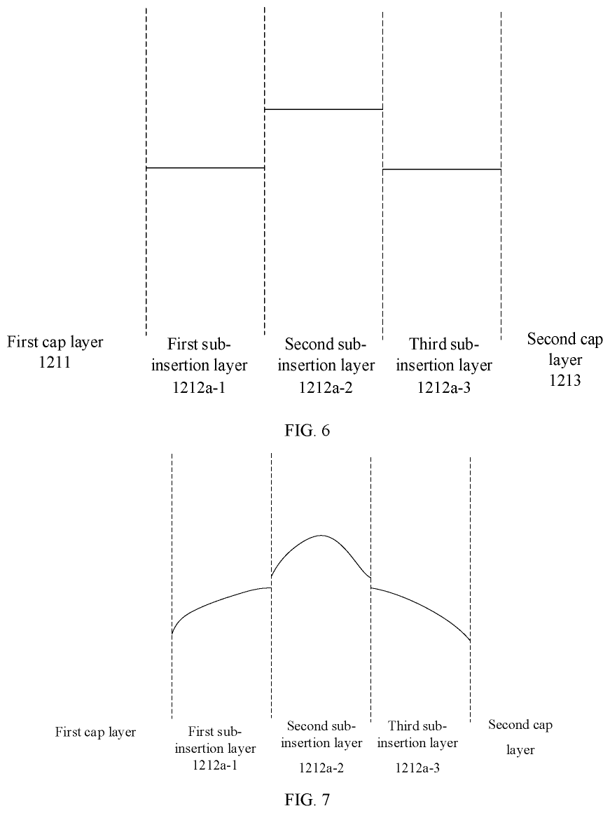

Referring to FIGS. 1 to 7, FIG. 1 is a schematic structural diagram of a transistor device according to an embodiment of the disclosure. FIG. 2 is a schematic structural diagram of a cap layer of the transistor device shown in FIG. 1. FIG. 3 is a schematic diagram showing a variation manner of a bandgap of a material in the cap layer shown in FIG. 2. FIG. 4 is an energy band diagram of the structure shown in FIG. 3. FIG. 5 is a schematic structural diagram of another cap layer of the transistor device shown in FIG. 1. FIG. 6 is a schematic diagram showing a variation manner of a bandgap of a material in the cap layer shown in FIG. 5. FIG. 7 is a schematic diagram showing another variation manner of a bandgap of a material in the cap layer shown in FIG. 5.

The transistor device provided in an embodiment of the disclosure includes a substrate 11, a compound semiconductor composite structure 12 having a two-dimensional electron gas, and a cap layer 121 disposed on the compound semiconductor composite structure 12. The cap layer 121 includes a first cap layer 1211 disposed on the compound semiconductor composite structure 12, an insertion layer 1212 disposed on the first cap layer 1211, and a second cap layer 1213 disposed on the insertion layer 1212. A bandgap of a material of the insertion layer 1212 is greater than bandgaps of materials of the first cap layer 1211 and the second cap layer 1213. A gate metal 13 is disposed on the second cap layer 1213.

In some embodiments, the gate metal 13 forms a Schottky contact or an ohmic contact with the second cap layer 1213.

In the related art, the material of the entire cap layer is the same, with almost no bandgap difference. A Schottky or ohmic contact is formed between the gate metal and the cap layer, resulting in a relatively large gate leakage current when the device is turned on, i.e., on-state gate leakage. In the embodiments of the disclosure, by providing the insertion layer 1212 between the first cap layer 1211 and the second cap layer 1213, and by making the bandgap of the material of the insertion layer 1212 greater than the bandgap of the material of the second cap layer 1213, a spike is generated in the energy band of the cap layer 121, with spikes in both the conduction band and the valence band, thereby blocking the flow of both electrons and holes, reducing the current magnitude in the cap layer 121, thus reducing on-state gate leakage, increasing the gate voltage withstand capability and voltage withstand swing of the device, and improving the gate reliability of the device.

In one embodiment, the transistor device is a GaN-based HEMT device. It is understood that the disclosure is not limited to GaN-based HEMT devices and may be applicable to other devices suffering from on-state gate leakage.

In one embodiment, along the direction from the first cap layer 1211 to the second cap layer 1213, the bandgap of the material of the insertion layer 1212 first increases and then decreases. By configuring the bandgap of the material of the insertion layer 1212 to be varied, polarization occurs between the insertion layer 1212 and the first cap layer 1211 and the second cap layer 1213, making the spike generated in the energy band of the cap layer 121 more pronounced, further reducing on-state gate leakage.

In one embodiment, as shown in FIG. 2, the insertion layer 1212 is a single-layer film structure. In an alternative embodiment, as shown in FIG. 3, along the direction from the first cap layer 1211 to the second cap layer 1213, the bandgap of the material of the insertion layer 1212 first gradually increases and then gradually decreases, i.e., the bandgap is largest in the middle portion of the insertion layer 1212 and gradually decreases toward both sides. The bandgap of the material at the surface of the insertion layer 1212 contacting the first cap layer 1211 and the bandgap of the material at the surface contacting the second cap layer 1213 may be the same or different, depending on design requirements. For example, the insertion layer 1212 may be grown by metal-organic chemical vapor deposition (MOCVD), in which the gas flow ratio is adjusted to form the insertion layer 1212 with a varying material bandgap. For example, the material of the insertion layer 1212 is AlGaN, the Al composition at the surface contacting the first cap layer 1211 is 0 (i.e., bandgap is 0), the Al composition at the surface contacting the second cap layer 1213 is 0 (i.e., bandgap is 0), and the highest Al composition inside the insertion layer 1212 is 0.05-0.4, achieving a good on-state gate leakage reduction effect. For AlGaN, the sum of Al composition and Ga composition is 1, the higher the Al composition, the lower the Ga composition, and the larger the bandgap.

As can be seen from the energy band diagram shown in FIG. 4, by providing the insertion layer 1212 with a varying material bandgap, a spike is generated in the middle of the energy band of the cap layer 121, with spikes in both the conduction band and the valence band, simultaneously blocking the flow of electrons and holes, thereby reducing the current magnitude in the cap layer 121.

In addition, configuring the bandgap of the material of the insertion layer 1212 to first gradually increase and then gradually decrease along the direction from the first cap layer 1211 to the second cap layer 1213 can reduce stress mismatch caused by abrupt changes in material bandgap, weaken the polarization between the insertion layer 1212 and the first cap layer 1211 and the second cap layer 1213, improve the growth quality of the insertion layer 1212, the first cap layer 1211, and the second cap layer 1213, thereby reducing interface charges and interface states at the interfaces between the insertion layer 1212 and the first cap layer 1211 and between the insertion layer 1212 and the second cap layer 1213. Interface states include interface charges and interface traps, etc., which helps reduce gate leakage and avoid issues such as dynamic threshold voltage drift.

In other embodiments, along the direction from the first cap layer 1211 to the second cap layer 1213, the bandgap of the material of the insertion layer 1212 first increases stepwise and then decreases stepwise.

In one embodiment, as shown in FIG. 5, the insertion layer 1212 is a multilayer film structure. The insertion layer 1212 includes 2n+1 sub-insertion layers 1212a, where n is greater than or equal to 1, each sub-insertion layer has the same thickness, and the thickness direction is the direction from the first cap layer to the second cap layer. The bandgap of the material of the (n+1)-th sub-insertion layer 1212a is greater than the bandgap of the material of the n-th sub-insertion layer 1212a, and the bandgap of the material of the (n+1)-th sub-insertion layer 1212a is greater than the bandgap of the material of the (n+2)-th sub-insertion layer 1212a, thereby achieving that along the direction from the first cap layer 1211 to the second cap layer 1213, the bandgap of the material of the insertion layer 1212 first increases and then decreases. The material of each sub-insertion layer 1212a may be the same. For example, n=1, and the insertion layer 1212 includes three sub-insertion layers 1212a.

By inserting several sub-insertion layers 1212a with different material bandgaps between the first cap layer 1211 and the second cap layer 1213, the bandgap of the insertion layer 1212 varies, and polarization occurs between the insertion layer 1212 and the first cap layer 1211 and the second cap layer 1213, making the spike generated in the energy band of the cap layer 121 more pronounced, further reducing on-state gate leakage.

In an alternative embodiment, the material bandgap of each sub-insertion layer 1212a is constant throughout. For example, as shown in FIG. 6, n=1, the insertion layer 1212 includes three sub-insertion layers 1212a, defined as a first sub-insertion layer 1212a-1, a second sub-insertion layer 1212a-2, and a third sub-insertion layer 1212a-3. The first sub-insertion layer 1212a-1 is located on the side of the second sub-insertion layer 1212a-2 closer to the first cap layer 1211, and the third sub-insertion layer 1212a-3 is located on the side of the second sub-insertion layer 1212a-2 closer to the second cap layer 1213. The material bandgap of the first sub-insertion layer 1212a-1 is constant throughout, the material bandgap of the second sub-insertion layer 1212a-2 is constant throughout, and the material bandgap of the third sub-insertion layer 1212a-3 is constant throughout. The material bandgap of the second sub-insertion layer 1212a-2 is greater than the material bandgap of the first sub-insertion layer 1212a-1, and the material bandgap of the second sub-insertion layer 1212a-2 is greater than the material bandgap of the third sub-insertion layer 1212a-3. The material bandgap of the first sub-insertion layer 1212a-1 is the same as the material bandgap of the third sub-insertion layer 1212a-3.

In an alternative embodiment, the material bandgap of each sub-insertion layer 1212a is configured to vary throughout. For example, as shown in FIG. 7, n=1, the insertion layer 1212 includes three sub-insertion layers 1212a, defined as a first sub-insertion layer 1212a-1, a second sub-insertion layer 1212a-2, and a third sub-insertion layer 1212a-3. The first sub-insertion layer 1212a-1 is located on the side of the second sub-insertion layer 1212a-2 closer to the first cap layer 1211, and the third sub-insertion layer 1212a-3 is located on the side of the second sub-insertion layer 1212a-2 closer to the second cap layer 1213. Along the direction from the first cap layer 1211 to the second cap layer 1213, the material bandgap of the first sub-insertion layer 1212a-1 gradually increases, the material bandgap of the second sub-insertion layer 1212a-2 first gradually increases and then gradually decreases, and the material bandgap of the third sub-insertion layer 1212a-3 gradually decreases. The material bandgap of the second sub-insertion layer 1212a-2 at the surface adjacent to the first sub-insertion layer 1212a-1 is greater than the material bandgap of the first sub-insertion layer 1212a-1 at the surface adjacent to the second sub-insertion layer 1212a-2, and the material bandgap of the second sub-insertion layer 1212a-2 at the surface adjacent to the third sub-insertion layer 1212a-3 is greater than the material bandgap of the third sub-insertion layer 1212a-3 at the surface adjacent to the second sub-insertion layer 1212a-2. Through the above configuration, the variation of the material bandgap of the insertion layer 1212 is approximately continuous and gradual, which can reduce stress mismatch caused by abrupt changes in material bandgap.

It should be noted that the material bandgaps of the first sub-insertion layer 1212a-1, the second sub-insertion layer 1212a-2, and the third sub-insertion layer 1212a-3 described above are varying, the sub-insertion layers 1212a can be grown by MOCVD, and the gas flow ratio is adjusted to form the sub-insertion layers 1212a with varying material bandgaps.

In one embodiment, the first cap layer 1211 and the second cap layer 1213 are both PGaN layers, and their material may both be P-type GaN.

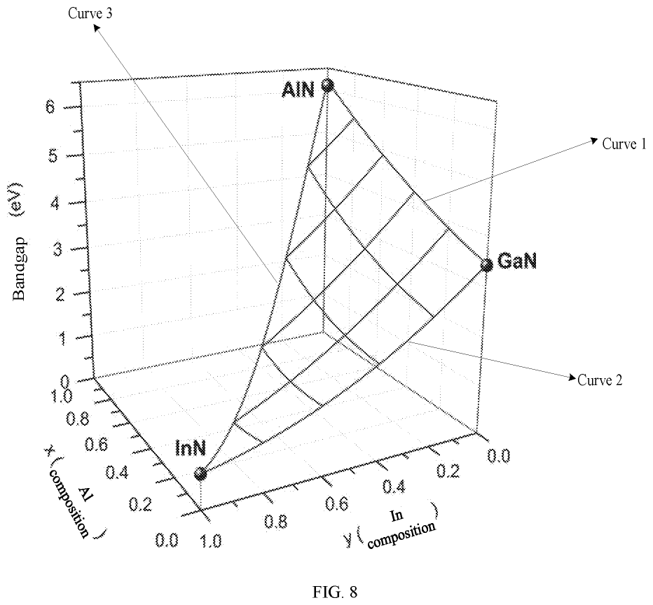

In one embodiment, the material of the insertion layer 1212 is AlₓIn_{y}Ga_{1-x-y}N, where x is greater than 0 and less than or equal to 1 (0<x≤1), y is greater than or equal to 0 and less than or equal to 1 (0≤y≤1), and x+y is greater than 0 and less than or equal to 1 (0<x+y≤1). The sum of the compositions of Al, In, and Ga is 1. Referring to FIG. 8, FIG. 8 is a diagram showing the relationship between the bandgap and composition of AlₓIn_{y}Ga_{1-x-y}N.

The bandgap of AlₓIn_{y}Ga_{1-x-y}N satisfies the following formula:

$$Eg = xEg ( AlN ) + ( 1 - x - y ) Eg ( GaN ) + yEg ( InN ) - {b}_{Al} x ( 1 - x ) - {b}_{In} y ( 1 - y ) .$$

At room temperature, Eg(AlN)=6.026 eV, Eg(GaN)=3.39 eV, Eg(InN)=1.9 or 0.7 eV, and b_{Al} and b_{In} are related to the growth process. In FIG. 8, x represents the Al composition, y represents the In composition. Curve 1 represents AlGaN, curve 2 represents InGaN, and curve 3 represents AlInN. As can be seen from FIG. 8, since the materials of the first cap layer 1211 and the second cap layer 1213 both include PGaN, it is sufficient that the bandgap of the insertion layer 1212 is greater than the bandgap of GaN, and AlInN without Ga composition is also acceptable. The bandgap of AlGaN is always greater than that of GaN. The bandgap of InGaN is always less than that of GaN. The bandgap of AlInN covers a wide range, partly greater than that of GaN and partly less than that of GaN. The bandgap of the material of the insertion layer 1212 varies continuously. It is also feasible that at the maximum bandgap Eg, the material is AlN, gradually transitioning to AlGaN, AlInN, or AlInGaN.

In an alternative embodiment, when y=0 and 0<x≤1, along the direction from the first cap layer 1211 to the second cap layer 1213, the Al composition in the insertion layer 1212 first increases and then decreases. At this time, the bandgap of the insertion layer 1212 is:

$$Eg = xEg ( AlN ) + ( 1 - x ) Eg ( GaN ) - {b}_{Al} x ( 1 - x ) , where {b}_{Al} = 1.3 .$$

The Al composition in the insertion layer 1212 first increases and then decreases, the Ga composition first decreases and then increases, and the bandgap of the insertion layer 1212 first increases and then decreases. For example, x=0.5, the material of the insertion layer 1212 is AlGaN.

The In composition in the insertion layer 1212 first decreases and then increases, the Ga composition first increases and then decreases, and the bandgap of the insertion layer 1212 first increases and then decreases. For example, y=0.5, the material of the insertion layer 1212 is InGaN.

In an alternative embodiment, when x=⅓ and y=⅓, the material of the insertion layer 1212 is AlInGaN, and the bandgap is jointly determined by the compositions of In, Al, and Ga.

In some embodiments, for a given y, along the direction from the first cap layer 1211 to the second cap layer 1213, the Al composition in the insertion layer 1212 first increases and then decreases, and the bandgap of the insertion layer 1212 first increases and then decreases.

In other embodiments, for a given x, along the direction from the first cap layer 1211 to the second cap layer 1213, the In composition in the insertion layer 1212 first decreases and then increases, and the bandgap of the insertion layer 1212 first increases and then decreases.

It should be understood that when both x and y vary, the change in the bandgap of AlₓIn_{y}Ga_{1-x-y}N depends on the direction and magnitude of change of x and the direction and magnitude of change of y. For example, when both x and y increase, if the increase in x is greater than the increase in y, then the bandgap of AlₓIn_{y}Ga_{1-x-y}N depends on the change in x; if the increase in x is less than the increase in y, then the bandgap depends on the change in y.

Exemplarily, along the direction from the first cap layer 1211 to the second cap layer 1213, the Al composition in the insertion layer 1212 first increases from x1 to x2 and then decreases to x3, while the In composition first increases from y1 to y2 and then decreases to y3. In the stage where the difference between x2 and x1 is greater than the difference between y2 and y1, the bandgap variation trend of the insertion layer 1212 mainly depends on the Al composition, and the bandgap increases along the direction from the first cap layer 1211 to the second cap layer 1213. Moreover, the difference between x2 and x3 is also greater than the difference between y2 and y3, so in this stage the bandgap variation trend of the insertion layer 1212 mainly depends on the Al composition, and the bandgap decreases along the direction from the first cap layer 1211 to the second cap layer 1213.

Exemplarily, along the direction from the first cap layer 1211 to the second cap layer 1213, the Al composition in the insertion layer 1212 first increases from x4 to x5 and then decreases to x6, while the In composition first increases from y4 to y5 and then increases to y6. In the stage where the difference between x5 and x4 is greater than the difference between y5 and y4, the bandgap variation trend of the insertion layer 1212 mainly depends on the Al composition, and the bandgap increases along the direction from the first cap layer 1211 to the second cap layer 1213. In the stage from Al composition x5 to x6 and In composition y5 to y6, the bandgap variation trend of the insertion layer 1212 is affected by both the Al and In compositions, and the bandgap variation trends of the Al and In compositions are consistent, so the bandgap decreases along the direction from the first cap layer 1211 to the second cap layer 1213.

Exemplarily, along the direction from the first cap layer 1211 to the second cap layer 1213, the Al composition in the insertion layer 1212 first increases from x7 to x8 and then decreases to x9, while the In composition first decreases from y7 to y8 and then increases to y9. In the stage from Al composition x7 to x8 and In composition y7 to y8, the bandgap variation trend of the insertion layer 1212 is affected by both the Al and In compositions, and the bandgap variation trends of the Al and In compositions are consistent, so the bandgap increases along the direction from the first cap layer 1211 to the second cap layer 1213. In the stage from Al composition x8 to x9 and In composition y8 to y9, the bandgap variation trend of the insertion layer 1212 is affected by both the Al and In compositions, and the bandgap variation trends of the Al and In compositions are consistent, so the bandgap decreases along the direction from the first cap layer 1211 to the second cap layer 1213.

Exemplarily, along the direction from the first cap layer 1211 to the second cap layer 1213, the Al composition in the insertion layer 1212 first increases from x10 to x11 and then increases to x12, while the In composition first increases from y10 to y11 and then increases to y12. In the stage where the difference between x11 and x10 is greater than the difference between y11 and y10, the bandgap variation trend of the insertion layer 1212 mainly depends on the Al composition, and the bandgap increases along the direction from the first cap layer 1211 to the second cap layer 1213. In the stage where the difference between y12 and y11 is greater than the difference between x12 and x11, the bandgap variation trend of the insertion layer 1212 mainly depends on the In composition, and the bandgap decreases along the direction from the first cap layer 1211 to the second cap layer 1213.

Exemplarily, along the direction from the first cap layer 1211 to the second cap layer 1213, the Al composition in the insertion layer 1212 first increases from x13 to x14 and then increases to x15, while the In composition first decreases from y13 to y14 and then increases to y15. In the stage from Al composition x13 to x14 and In composition y13 to y14, the bandgap variation trend of the insertion layer 1212 is affected by both the Al and In compositions, and the bandgap variation trends of the Al and In compositions are consistent, so the bandgap increases along the direction from the first cap layer 1211 to the second cap layer 1213. In the stage where the difference between y15 and y14 is greater than the difference between x15 and x14, the bandgap variation trend of the insertion layer 1212 mainly depends on the In composition, and the bandgap decreases along the direction from the first cap layer 1211 to the second cap layer 1213.

Exemplarily, along the direction from the first cap layer 1211 to the second cap layer 1213, the Al composition in the insertion layer 1212 first decreases from x16 to x17 and then increases to x18, while the In composition first decreases from y16 to y17 and then increases to y18. In the stage where the difference between x16 and x17 is less than the difference between y16 and y17, the bandgap variation trend of the insertion layer 1212 mainly depends on the In composition, and the bandgap increases along the direction from the first cap layer 1211 to the second cap layer 1213. Moreover, in the stage where the difference between x18 and x17 is less than the difference between y18 and y17, the bandgap variation trend of the insertion layer 1212 mainly depends on the In composition, and the bandgap decreases along the direction from the first cap layer 1211 to the second cap layer 1213.

Exemplarily, along the direction from the first cap layer 1211 to the second cap layer 1213, the Al composition in the insertion layer 1212 first decreases from x19 to x20 and then decreases to x21, while the In composition first decreases from y19 to y20 and then increases to y21. In the stage where the difference between y19 and y20 is greater than the difference between x19 and x20, the bandgap variation trend of the insertion layer 1212 mainly depends on the In composition, and the bandgap increases along the direction from the first cap layer 1211 to the second cap layer 1213. In the stage from Al composition x20 to x21 and In composition y20 to y21, the bandgap variation trend of the insertion layer 1212 is affected by both the Al and In compositions, and the bandgap variation trends of the Al and In compositions are consistent, so the bandgap decreases along the direction from the first cap layer 1211 to the second cap layer 1213.

Exemplarily, along the direction from the first cap layer 1211 to the second cap layer 1213, the Al composition in the insertion layer 1212 first decreases from x22 to x23 and then decreases to x24, while the In composition first decreases from y22 to y23 and then decreases to y24. In the stage where the difference between y22 and y23 is greater than the difference between x22 and x23, the bandgap variation trend of the insertion layer 1212 mainly depends on the In composition, and the bandgap increases along the direction from the first cap layer 1211 to the second cap layer 1213. In the stage where the difference between x23 and x24 is greater than the difference between y23 and y24, the bandgap variation trend of the insertion layer 1212 mainly depends on the Al composition, and the bandgap decreases along the direction from the first cap layer 1211 to the second cap layer 1213.

In one embodiment, the thickness of the first cap layer 1211 is 2 nanometers (nm) to 100 nm; and/or the thickness of the insertion layer 1212 is 2 nm to 100 nm; and/or the thickness of the second cap layer 1213 is 2 nm to 100 nm. By designing the thicknesses of the first cap layer 1211, the insertion layer 1212, and the second cap layer 1213 as described above, the energy band can be adjusted, the current can be controlled, and thus on-state gate leakage can be reduced.

Exemplarily, the thickness of the first cap layer 1211 is 50 nm to 100 nm.

Exemplarily, the thickness of the insertion layer 1212 is 5 nm to 50 nm.

Exemplarily, the thickness of the second cap layer 1213 is 5 nm to 50 nm.

In one embodiment, the insertion layer 1212 is undoped.

In one embodiment, the insertion layer 1212 is P-doped.

In one embodiment, the insertion layer 1212 is N-doped.

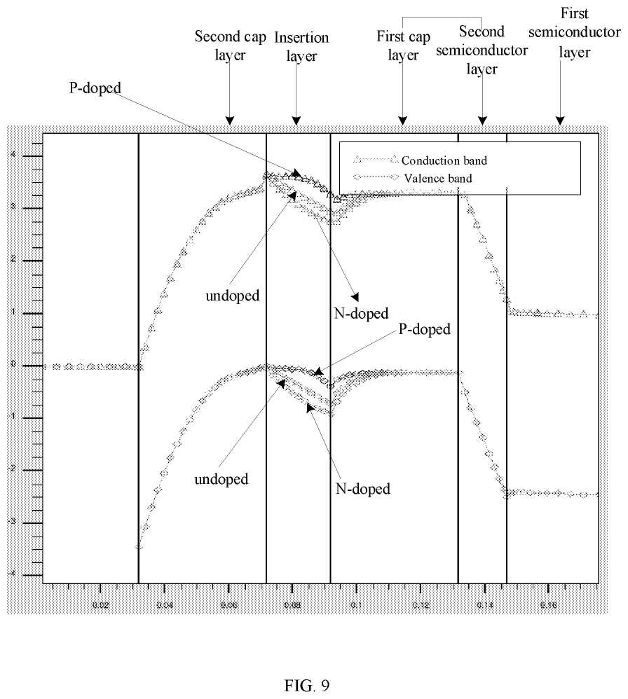

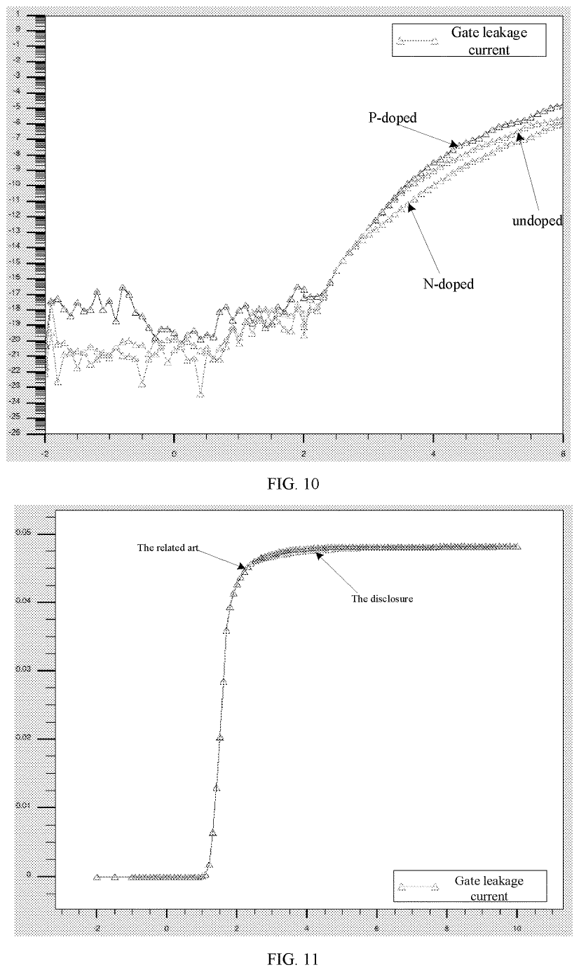

It should be noted that, as shown in FIG. 9, FIG. 9 is a schematic diagram comparing energy bands for different doping conditions of the insertion layer 1212 of the transistor device according to an embodiment of the disclosure. For the degree of band bending: P-doped insertion layer 1212<undoped insertion layer 1212<N-doped insertion layer 1212. As shown in FIG. 10, FIG. 10 is a schematic diagram comparing gate leakage currents for different doping conditions of the insertion layer 1212 of the transistor device according to an embodiment of the disclosure. For gate leakage current: P-doped insertion layer 1212>undoped insertion layer 1212>N-doped insertion layer 1212. The N-doped insertion layer 1212 can achieve a better effect of reducing on-state gate leakage.

Referring to FIG. 1, along the direction from the first cap layer 1211 to the second cap layer 1213, the compound semiconductor composite structure 12 having a two-dimensional electron gas includes a buffer layer 122, a first semiconductor layer 123, and a second semiconductor layer 124 stacked in sequence. A two-dimensional electron gas is formed between the first semiconductor layer 123 and the second semiconductor layer 124. The cap layer 121 is disposed on the surface of the second semiconductor layer 124 facing away from the first semiconductor layer 123.

In one embodiment, the material of the buffer layer 122 includes at least one of AlGaN, GaN, and InAlGaN. Exemplarily, the material of the buffer layer 122 is AlGaN. Exemplarily, the buffer layer 122 is a superlattice of alternating AlGaN and GaN materials.

In one embodiment, the material of the first semiconductor layer 123 includes one of GaN, AlGaN, and InAlGaN.

In one embodiment, the material of the second semiconductor layer 124 includes one of AlGaN, InGaN, and InAlGaN. It can be understood that when the material of the second semiconductor layer 124 includes AlGaN, and the first cap layer 1211 in the cap layer 121 contacts the second semiconductor layer 124, and the material of the first cap layer 1211 includes PGaN, it is advantageous to deplete the two-dimensional electron gas between the first semiconductor layer 123 and the second semiconductor layer 124, thereby forming an enhancement-mode device.

Referring to FIG. 1, the transistor device further includes a source electrode 14 and a drain electrode 15, which are disposed on the side of the second semiconductor layer 124 facing away from the substrate 11 and above the two-dimensional electron gas. The cap layer 121 is laterally located between the source electrode 14 and the drain electrode 15.

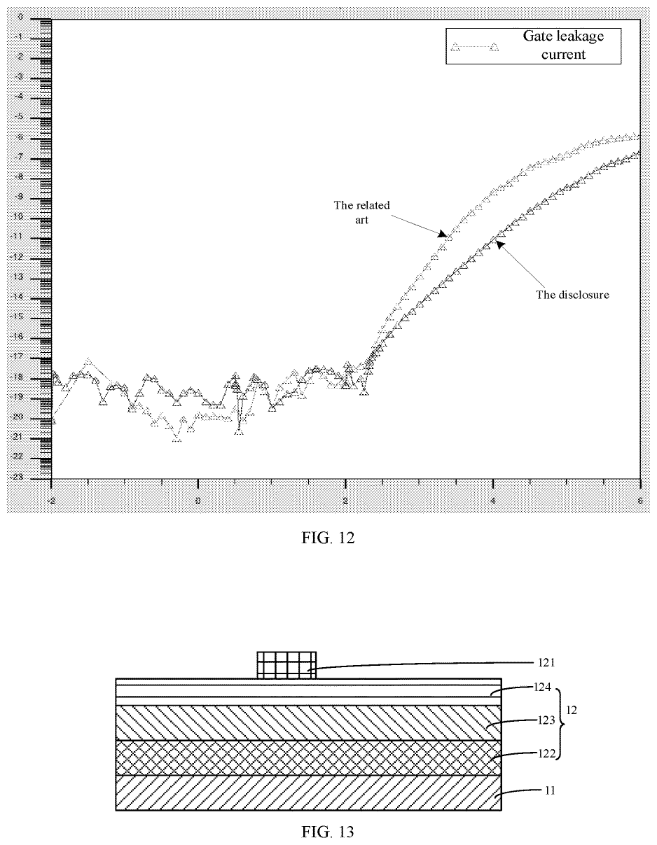

Referring to FIGS. 11 and 12, FIG. 11 is an experimental comparison diagram of ID-VG between the transistor device according to the embodiment of the disclosure and an existing transistor device, and FIG. 12 is an experimental comparison diagram of I_{G}-V_{G} between the transistor device according to the embodiment of the disclosure and the existing transistor device.

The disclosure also conducts experimental comparisons between the transistor device provided in the embodiment and the existing transistor device. In FIG. 11, the abscissa represents the applied gate voltage V_{G}, the ordinate represents current, I_{D} represents the on-state current of the device, and I_{G} represents the gate leakage current of the device. In this experiment, the only difference between the existing transistor device and the transistor device of the embodiment of the disclosure is the structure of the cap layer. The cap layer of the existing transistor device is a single-layer film structure, and the material includes PGaN. The cap layer 121 of the transistor device used in the experiment is the cap layer 121 shown in FIG. 2.

As shown in FIG. 11, the I_{D} of the transistor device provided in the embodiment of the disclosure is substantially unchanged compared to that of the existing transistor device, indicating that providing the insertion layer 1212 between the first cap layer 1211 and the second cap layer 1213 does not affect the on-resistance. As shown in FIG. 12, when V_{G} is greater than 0 V, the I_{G} of the transistor device provided in the embodiment of the disclosure is lower than that of the existing transistor device, indicating that the transistor device provided in the embodiment of the disclosure can reduce on-state gate leakage. Lower on-state gate leakage indicates that the gate voltage withstand capability and gate voltage swing of the device are improved, and the gate reliability of the device is also enhanced.

When the transistor device is normally operated, the voltage applied to the gate is 6 volts (V). As shown in FIG. 12, at an abscissa of 6 V, the I_{G} of the transistor device provided in the embodiment of the disclosure is lower than that of the existing transistor device, i.e., the transistor device provided in the embodiment of the disclosure reduces the leakage current.

Referring to FIG. 13, an embodiment of the disclosure further provides a semiconductor epitaxial structure. The semiconductor epitaxial structure includes a substrate 11, a compound semiconductor composite structure 12 having a two-dimensional electron gas, and a cap layer 121 disposed on the compound semiconductor composite structure 12. The cap layer 121 includes a first cap layer 1211 disposed on the compound semiconductor composite structure 12, an insertion layer 1212 disposed on the first cap layer 1211, and a second cap layer 1213 disposed on the insertion layer 1212. A bandgap of a material of the insertion layer 1212 is greater than bandgaps of materials of the first cap layer 1211 and the second cap layer 1213. A gate metal 13 is disposed on the second cap layer 1213.

In the related art, the material of the entire cap layer is the same, with almost no bandgap difference. A Schottky or ohmic contact is formed between the gate metal and the cap layer, resulting in a relatively large gate leakage current when the device is turned on, i.e., on-state gate leakage. In the embodiments of the disclosure, by providing the insertion layer 1212 between the first cap layer 1211 and the second cap layer 1213, and by making the bandgap of the material of the insertion layer 1212 greater than the bandgap of the material of the second cap layer 1213, a spike is generated in the energy band of the cap layer 121, with spikes in both the conduction band and the valence band, thereby blocking the flow of both electrons and holes, reducing the current magnitude in the cap layer 121, thus reducing on-state gate leakage, increasing the gate voltage withstand capability and voltage withstand swing of the device, and improving the gate reliability of the device.

In some embodiments, along the direction from the first cap layer 1211 to the second cap layer 1213, the bandgap of the material of the insertion layer 1212 first increases and then decreases. By configuring the bandgap of the material of the insertion layer 1212 to be varied, polarization occurs between the insertion layer 1212 and the first cap layer 1211 and the second cap layer 1213, making the spike generated in the energy band of the cap layer 121 more pronounced, further reducing on-state gate leakage.

It should be noted that for the specific configuration, material selection, and achievable technical effects of the insertion layer in the semiconductor epitaxial structure of this embodiment, reference may be made to the related description of the insertion layer 1212 in the semiconductor device above, and details will not be repeated here.

An embodiment of the disclosure further provides a preparation method of a semiconductor epitaxial structure, the method comprising:
providing a substrate;
forming a compound semiconductor composite structure having a two-dimensional electron gas on the substrate; and
forming a cap layer on the compound semiconductor composite structure, the cap layer including a first cap layer disposed on the compound semiconductor composite structure, an insertion layer disposed on the first cap layer, and a second cap layer disposed on the insertion layer; wherein a bandgap of a material of the insertion layer is greater than bandgaps of materials of the first cap layer and the second cap layer, respectively; and along a direction from the first cap layer to the second cap layer, the bandgap of the material of the insertion layer first increases and then decreases.

Exemplarily, the compound semiconductor composite structure may be a Group III-V compound semiconductor composite structure.

Exemplarily, forming the compound semiconductor composite structure having a two-dimensional electron gas on the substrate may be performed by growing the compound semiconductor composite structure having a two-dimensional electron gas on the substrate using known semiconductor epitaxial growth methods such as chemical vapor deposition.

For the technical effects achievable by the insertion layer in the semiconductor epitaxial structure fabricated by this method, reference may be made to the related description of the insertion layer 1212 in the semiconductor device above, and details will not be repeated here.

The above are only embodiments of the disclosure and are not intended to limit the scope of the patent of the disclosure. Any equivalent structure or equivalent process transformation made using the specification and drawings of the disclosure, or direct or indirect application in other related technical fields, shall be similarly included in the scope of patent protection of the disclosure.

What is claimed is:

1. A transistor device, comprising:
a substrate;
a compound semiconductor composite structure, having a two-dimensional electron gas, disposed on the substrate;
a first cap layer, disposed on the compound semiconductor composite structure;
an insertion layer, disposed on the first cap layer;
a second cap layer, disposed on the insertion layer; wherein a bandgap of a material of the insertion layer is greater than bandgaps of materials of the first cap layer and the second cap layer, respectively; and along a direction from the first cap layer to the second cap layer, the bandgap of the material of the insertion layer first increases and then decreases; and
a gate metal, disposed on the second cap layer.

2. The transistor device as claimed in claim 1, wherein, along the direction from the first cap layer to the second cap layer, the bandgap of the material of the insertion layer first gradually increases and then gradually decreases.

3. The transistor device as claimed in claim 1, wherein, along the direction from the first cap layer to the second cap layer, the bandgap of the material of the insertion layer first increases stepwise and then decreases stepwise.

4. The transistor device as claimed in claim 3, wherein the insertion layer comprises 2n+1 sub-insertion layers, n is greater than or equal to 1, each of the sub-insertion layers has a same thickness, and a thickness direction is the direction from the first cap layer to the second cap layer; and
a bandgap of a material of a (n+1)-th sub-insertion layer is greater than a bandgap of a material of a n-th sub-insertion layer, and the bandgap of the material of the (n+1)-th sub-insertion layer is greater than a bandgap of a material of a (n+2)-th sub-insertion layer;

5. The transistor device as claimed in claim 1, wherein the first cap layer and the second cap layer are both P-type gallium nitride (GaN) layers.

6. The transistor device as claimed in claim 1, wherein the material of the insertion layer is AlₓIn_{y}Ga_{1-x-y}N, where x is greater than 0 and less than or equal to 1, y is greater than or equal to 0 and less than or equal to 1, and x+y is greater than 0 and less than or equal to 1.

7. The transistor device as claimed in claim 6, wherein, with the y being constant, along the direction from the first cap layer to the second cap layer, a composition of aluminum (Al) in the insertion layer first increases and then decreases.

8. The transistor device as claimed in claim 6, wherein, with the x being constant, along the direction from the first cap layer to the second cap layer, a composition of indium (In) in the insertion layer first decreases and then increases.

9. A semiconductor epitaxial structure, comprising:
a substrate;
a compound semiconductor composite structure, having a two-dimensional electron gas, disposed on the substrate; and
a cap layer, disposed on the compound semiconductor composite structure, the cap layer comprising:
a first cap layer, disposed on the compound semiconductor composite structure,
an insertion layer, disposed on the first cap layer, and
a second cap layer, disposed on the insertion layer; and
wherein a bandgap of a material of the insertion layer is greater than bandgaps of materials of the first cap layer and the second cap layer, respectively; and along a direction from the first cap layer to the second cap layer, the bandgap of the material of the insertion layer first increases and then decreases.

10. The epitaxial structure as claimed in claim 9, wherein, along the direction from the first cap layer to the second cap layer, the bandgap of the material of the insertion layer first gradually increases and then gradually decreases.
